(19) United States
(12) Patent Application Publication
(10) Pub. No.: US 2026/0287630 A1
(43) Pub. Date: Sep. 24, 2026

(54) RF TESTING EQUIPMENT AND SYSTEM, AND CALIBRATION METHOD FOR RF TRANSMISSION CHARACTERISTIC

(71) Applicant: INDUSTRIAL TECHNOLOGY RESEARCH INSTITUTE, Hsinchu (TW)

(72) Inventors: Huan-Ta CHEN, Hsinchu County (TW); Ching-Wen CHIANG, Hsinchu City (TW); Ming Jie YU, Hsinchu County (TW); Chen-Wei LEE, New Taipei City (TW); Te-Ming CHEN, Taipei City (TW); Yu-An CHANG, New Taipei City (TW); Chu Hung LI, Taoyuan City (TW)

(73) Assignee: INDUSTRIAL TECHNOLOGY RESEARCH INSTITUTE, Hsinchu (TW)

(21) Appl. No.: 19/189,722

(22) Filed: Apr. 25, 2025

(30) Foreign Application Priority Data
Mar. 19, 2025 (TW) 114110314

(51) Int. Cl. G01R 29/08; G01R 35/00

(52) U.S. Cl. CPC G01R 29/0871; G01R 35/005

(57) ABSTRACT

An RF testing equipment, an RF testing system, or a calibration method for an radio frequency (RF) transmission characteristic is suitable for over-the-air (OTA) test environment. The RF testing equipment includes an RF signal generator, a primary channel, a measurement channel, and a receiver. The RF signal generator provides a test signal in the millimeter-wave frequency band. The primary channel, electrically connected to the RF signal generator, transmits the test signal to a device under test (DUT). The measurement channel senses an RF signal radiated by the DUT. The receiver, electrically connected to both the primary and measurement channels, calculates calculate an RF transmission characteristic of the DUT according to the RF signal.

### CROSS-REFERENCE TO RELATED APPLICATIONS

This application is based on, and claims priority of Taiwan Patent Application No. 114110314, filed on Mar. 19, 2025, the entirety of which is incorporated by reference herein.

### TECHNICAL FIELD

This technical field relates to over-the-air (OTA) testing and also relates to a radio frequency (RF) testing equipment and system, and calibration method for RF transmission characteristics.

### BACKGROUND

With the rapid advancement of wireless communication technologies, testing requirements for radio frequency (RF) and microwave equipment are gradually shifting from conducted testing to over-the-air (OTA) testing. Wireless devices, such as antenna array packages, wireless communication modules, and RF front-end components, operate in OTA test environment; therefore, the test environment should correspond to actual usage conditions. However, performing accurate harmonic measurements in OTA test environment remains a significant challenge due to the following technical issues:

1. In OTA test environment, the RF signal transmission is affected by multipath effects, scattering, and environmental reflections, resulting in less stable measurement outcomes compared to conducted tests. 2. Traditional Short-Open-Load-Through (SOLT) calibration requires the use of physical calibration standards to compensate for measurement errors; however, such standard calibration methods cannot be applied in OTA test environments. 3. In OTA test environment, a measurement method using a vector network analyzer (VNA) can be used to measure transmission parameters, such as scattering parameters (S-parameters). The S-parameters include S11 (input port voltage reflection coefficient), S21 (forward voltage gain), S12 (reverse voltage gain), and S22 (output port voltage reflection coefficient). Nevertheless, because the device under test (DUT) cannot be directly connected to the VNA test ports in OTA settings, traditional VNA testing methods are not suitable for free-space testing.

U.S. Pat. No. 6,316,945B1 recites a VNA and its testing method for use in RF and microwave measurements. The testing method of the VNA is widely applied to the measurement of the S-parameters, primarily through the establishment of a through line for normalization. By calculating signal ratios, the method eliminates error sources in the test system, thereby allowing accurate evaluation of the frequency response and impedance matching characteristics of the DUT, and ultimately enhancing the precision of harmonic measurements.

However, the aforementioned testing method does not take into account the specific requirements of OTA testing, and thus has the following limitations when applied to wireless device testing: 1. The DUT must be directly connected to the VNA through test ports, which is not feasible in OTA test environments. 2. The SOLT (Short, Open, Load, Thru) calibration relies on physical calibration standards, which cannot be applied in OTA test scenarios. 3. The method lacks an error compensation mechanism specifically designed for OTA testing, which may result in the measurement outcomes being influenced.

Addressing these challenges requires the development of improved testing methodologies tailored for OTA environments, to enhance measurement accuracy and reliability in OTA test environment.

### SUMMARY

According to some embodiments, an RF testing equipment, an RF testing system, or a calibration method for a radio frequency (RF) transmission characteristic is suitable for over-the-air (OTA) test environment, and to provide a vector network analyzer (VNA) structure suitable for unidirectional testing conditions, enabling calibration of RF characteristics. For example, RF gain, spectral response, and power compensation, at millimeter-wave (mmWave) and sub-terahertz (sub-THz) frequencies, and further supporting antenna-in-package (AiP) technology.

According to one embodiment, an RF testing equipment includes an RF signal generator, a primary channel, a measurement channel, and a receiver. The RF signal generator is configured to provide a test signal in a millimeter-wave frequency band. The primary channel is electrically coupled to the RF signal generator, and is configured to connect with a device under test (DUT) and transmit the test signal to the DUT. The measurement channel is configured to sense an RF signal radiated by the DUT. The receiver, electrically coupled to the primary channel and the measurement channel, is configured to calculate RF transmission characteristics of the DUT according to the RF signal.

According to one embodiment, an RF testing system includes an RF signal generator, two RF testing modules, and a power divider. The RF signal generator is configured to provide a test signal in a millimeter-wave frequency band. Each of the two RF testing modules includes a primary channel and a receiver. The primary channel is electrically connected to the RF signal generator, configured to connect to a device under test (DUT) and transmit the test signal to the DUT. The receiver is electrically connected to the primary channel and the measurement channel, and configured to calculate an RF transmission characteristic of the DUT according to the RF signal. The measurement channel includes a second RF coupler, a standard antenna, and a first signal input port. The second RF coupler is electrically connected to the receiver. The standard antenna is configured to sense and convert the RF signal within a far-field measurement range. The first signal input port is electrically connected to the standard antenna and the second RF coupler, and configured to couple the RF signal to the second RF coupler.

According to another embodiment, a calibration method for an RF transmission characteristic, performed by the RF testing equipment. The calibration method includes: obtaining, by the receiver, a reference gain and a reference output power from a reference device; providing, by the RF signal generator, the test signal in the millimeter-wave frequency band; transmitting, by the primary channel, the test signal to the DUT; sensing, by the measurement channel, the RF signal radiated by the DUT; and calculating, by the receiver, the RF transmission characteristic of the DUT according to the reference gain, the reference output power, and a measured output power of the DUT.

The above description and the embodiments provided herein serve to illustrate and explain the principles and spirit of the disclosure, facilitating further understanding of the scope set forth in the appended claims.

### BRIEF DESCRIPTION OF THE DRAWINGS

The present invention can be more fully understood by reading the subsequent detailed description and examples with references made to the accompanying drawings, wherein:

FIGS. 1 and 2 are schematic diagrams illustrating an RF testing equipment suitable for an OTA testing environment according to an embodiment.

FIG. 3 is a flowchart illustrating a calibration method for RF transmission characteristics according to an embodiment.

FIG. 4 is a vector diagram illustrating a calibration method for RF transmission characteristics according to an embodiment.

FIG. 5 is a flowchart illustrating a calibration method for RF transmission characteristics according to another embodiment.

FIG. 6 is a schematic diagram illustrating an RF testing system according to an embodiment.

FIG. 7 is a schematic diagram illustrating a vector network analyzer according to an embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown to simplify the drawing.

With advancements in wireless communication and millimeter-wave (hereafter referred to as mmWave) technologies, over-the-air (hereafter referred to as OTA) testing has become a critical procedure for evaluating the performance of antennas and RF systems, particularly in 5G/6G communications and low Earth orbit (hereafter referred to as LEO) satellite systems. In such systems, ensuring antenna transmission parameters—such as the forward transmission parameter S21—is essential. According to one embodiment of the present invention, an RF testing equipment suitable for an OTA test environment is provided, which is configured to measure RF transmission characteristics of a device under test (hereafter referred to as DUT). The RF testing equipment can verify the transmission gain of wireless communication modules and evaluate the electromagnetic properties of antennas within a wireless transmission environment. Such electromagnetic properties may include antenna gain, radiation pattern, polarization characteristics, equivalent isotropic radiated power (hereafter referred to as EIRP), receiver sensitivity, transmission parameters such as S21, or any combination thereof.

In an embodiment, the RF testing equipment may be implemented as a vector network analyzer (hereafter referred to as VNA), which is a precision instrument commonly used for measuring scattering parameters (hereafter referred to as S-parameters) of RF and microwave devices. For example, in a two-port network, measurements may include reflection parameters S11 and S22, the forward transmission parameter S21, and the reverse transmission parameter S12. In the OTA test environment, the DUT is typically configured as either a transmitter or a receiver, and thus only the forward transmission parameter S21 needs to be measured. However, prior to the OTA testing stage, two-port network measurements of reflection parameters S11 and S22, as well as the reverse transmission parameter S12, may be conducted on antenna arrays. These scattering parameters (e.g., S11, S22, and S12) are useful for evaluating impedance matching and mutual coupling characteristics of the antennas, as further described below.

In a two-port network, the reflection parameters S11 and S22 are measured to observe the degree of reflection at the input and other ports of the antenna, respectively. Adjustments to the corresponding matching networks or printed circuit board (hereafter referred to as PCB) structures can be made to reduce return loss. Additionally, the reverse transmission parameter S12 can be used to evaluate the coupling between individual antennas within an antenna array, thereby avoiding negative impacts on beamforming and the performance of multi-antenna systems. Isolation can further be enhanced by adding isolation structures or optimizing the spacing between components. Through this conducted testing process, the fundamental characteristics of the antenna can be verified in a controlled environment, which helps reduce interference and uncertainty during subsequent OTA testing and more accurately reflects the antenna's performance under actual application conditions.

In the embodiment, the RF testing equipment is applied to measure the gain of the DUT (hereafter referred to as GoD), specifically the transmission parameter S21, evaluating transmission efficiency of wireless RF signal in the OTA test environment. Through a calibration method, measurement accuracy is improved. The GoD characterizes signal transmission properties between the transmitting end (i.e., the DUT) and receiving end, and is used to confirm that antenna system gain, directionality, polarization, and power loss in the wireless environment conform to intended design criteria.

The OTA test environment differs from conventional conducted testing in that it relies on wireless signal transmission rather than physical cable connections to the DUT. In order to accurately measure the GOD, the test environment must include an anechoic chamber to eliminate environmental reflections and multipath effects. A reference antenna is used as the receiving end to standardize the measurement results. Since the VNA cannot be directly calibrated using the SOLT method in the OTA test environment, the EIRP calibration must be performed using the reference antenna to ensure the accuracy of the transmission gain measurement.

The measurement procedure begins with the generation of an RF signal from the transmission end of the DUT, and the signal is transmitted to the receiving end via a reference antenna. Upon reception, the reference antenna captures the RF signal and forwards it to a VNA for calculation of the transmission parameter S21, with appropriate compensation for free-space propagation losses. To minimize the impact of multipath effects on the measurement, the test environment must employ an anechoic chamber to shield against external interference and to ensure that the distance between the DUT and the receiving antenna satisfies the far-field condition, thereby enabling accurate S21 measurement results.

During the OTA testing phase, factors affecting the accuracy of the S21 measurement include multipath effects in wireless transmission, calibration of the test equipment, normalization of reference points, and the influence of free-space path loss. Multipath effects introduce reflected and diffracted components into the received signal, resulting in deviations in the measured values. Therefore, the use of an anechoic chamber to eliminate environmental reflections is essential. In addition, traditional SOLT calibration is not applicable to OTA testing; accordingly, EIRP calibration is adopted to ensure consistency in the test baseline and improve the reproducibility of the measurement results.

Furthermore, free-space transmission loss varies with the test distance and must be compensated in accordance with the Friis transmission equation.

The S21 measurement is applicable to 5G/6G massive MIMO array antennas, mmWave radars, LEO satellite communication systems, and other high-frequency RF systems. The resulting data can be used to evaluate antenna beamforming performance, wireless transmission gain, and signal loss, as well as to optimize the OTA testing environment and measurement procedures. In the OTA test environment, the S21 measurement enables precise assessment of wireless RF transmission gain in free space. Automatic calibration may be performed using the VNA and the reference antenna to compensate for environmental variations in the OTA testing environment. Unlike conventional conducted test environment, the S21 measurement in the OTA test environment should take multipath effects in wireless transmission, EIRP calibration, and free-space losses into consideration, and employ appropriate testing methodology to ensure measurement accuracy and consistency of the resulting data.

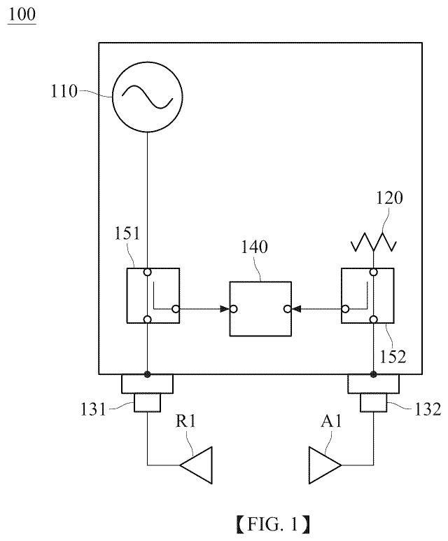

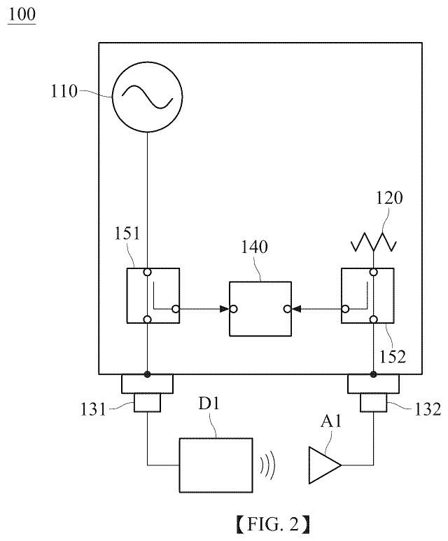

FIGS. 1 and 2 are schematic diagrams illustrating an RF testing equipment suitable for the OTA testing environment, according to an embodiment. As shown in FIGS. 1 and 2, the RF testing equipment suitable for the OTA testing environment may be implemented as a first VNA 100. The first VNA 100 includes an RF generator 110, a first RF load 120, a first signal output port 131, a first signal input port 132, a first receiver 140, a first coupler frequency (CF) 151, and a second coupler frequency 152. The first coupler 151 is electrically connected to the RF generator 110, the first signal output port 131, and the first receiver 140. The second coupler 152 is electrically connected to the first RF load 120, the first signal input port 132, and the first receiver 140. In FIG. 1, the first signal output port 131 is electrically connected to a reference device R1. In FIG. 2, the first signal output port 131 is electrically connected to a first DUT D1.

In this embodiment, an RF signal generator 110 (also referred to as RF Gen) within the first VNA generates an RF signal (also referred to as a test signal) suitable for mmWave frequencies. The test signal is transmitted to a reference device R1 or a first DUT D1 via the first signal output port 131. The first signal input port 132 is configured to receive the test signal through a first standard antenna A1, which provides the required driving or excitation energy for the first receiver 140. Upon receiving the unidirectional input signal, the reference device R1 or the DUT D1 processes the test signal via its internal circuitry or transmits energy through an antenna or equivalent mechanism, and then delivers the resulting signal to the first signal input port 132. At this phase, the VNA performs a measurement or reception function through a separate internal path, extracting power, spectrum, or other reference information from the signal at the first signal input port 132, without feeding the signal back to the first signal output port 131.

The RF generator 110 is configured to generate an RF signal. The first RF coupler 151 is configured to transmit the RF signal from the RF generator 110 to the first signal output port 131, and to couple the RF signal to the first receiver 140. The second RF coupler 152 is configured to transmit a first output signal (also referred to as a measurement result) from the first signal input port 132 to the first RF load 120, and to couple the first output signal to the first receiver 140.

The first VNA 100 may be configured to measure the RF transmission characteristics (e.g., gain of DUT, GoD) of a single DUT, such as the first DUT D1, in which the first signal output port 131 and the first signal input port 132 are communicatively connected through the first DUT D1. For example, the first DUT D1 is typically equipped with an antenna. The input end of the first DUT D1 is connected to the first signal output port 131 via a wired connection. The first signal input port 132 is connected to a first standard antenna A1 for receiving a first output signal wirelessly radiated by the first DUT D1. In some embodiments, the first DUT D1 can be equipped with an antenna array, but not limited thereto.

Although the first VNA 100 arranges both the primary channel (used for driving or transmission) and the measurement channel (used for data collection or monitoring) implemented in the same physical signal route, the two channels operate independently in terms of logic and function. The primary channel includes the first RF coupler 151 and the first signal output port 131. The first RF coupler 151 is electrically connected to the RF signal generator 110 and the first receiver 140, and configured to transmit the test signal. The first signal output port 131 is electrically connected to the first RF coupler 151, and configured to transmit the test signal to the DUT. The measurement channel includes the second RF coupler 152, the first standard antenna A1, and the first signal input port 132. The second RF coupler 152 is electrically connected to the first receiver 140. The first standard antenna A1 is configured to sense and convert the RF signal within a far-field measurement range. The first signal input port 132 is electrically connected to the first standard antenna A1 and the second RF coupler 152, and configured to couple the RF signal to the second RF coupler 152. This configuration enables simultaneous signal transmission and measurement without affecting the overall unidirectional output, requiring only verification of output quality without concern for signal reflections at the input end. Accordingly, in S-parameter applications involving OTA transmission between antennas, the architecture may be simplified to enable direct acquisition of transmission and reception data, along with real-time monitoring or calibration, without requiring signal feedback to the VNA for high-precision vector comparison.

Overall, the first vector network analyzer (VNA) 100 maintains unidirectional signal transmission while separating transmission and measurement functions into two independent channels for parallel processing. This configuration reduces circuit switching complexity and enables a continuous, uninterrupted signal detection process.

At the same time, the first VNA 100 retains the flexibility to be extended for free-space measurement or to be integrated into RF modules as an active component.

Whether deployed in an OTA testing environment for antenna arrays, or in other system scenarios requiring only input-to-output signal monitoring, this design enables measurement and calibration functions to be achieved in a relatively simplified manner.

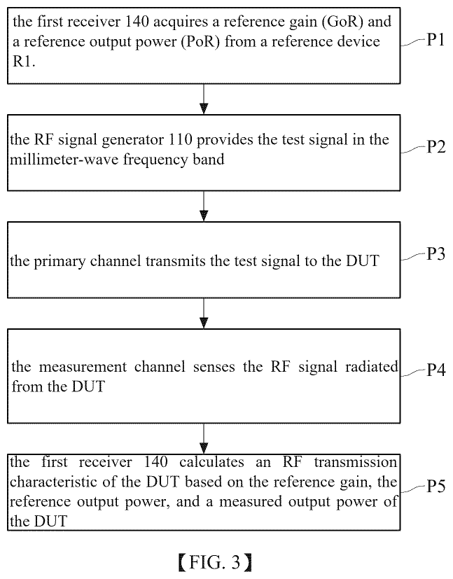

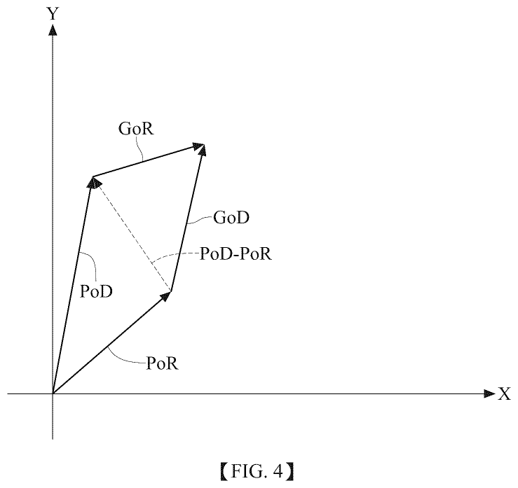

FIG. 3 illustrates a flowchart of a calibration method for an RF transmission characteristic according to an embodiment. The calibration method is executed by first VNA 100 shown in FIG. 1, and including Steps P1 through P5. In Step P1, the first receiver 140 acquires a reference gain (GoR) and a reference output power (POR) from a reference device R1. In Step P2, the RF signal generator 110 provides the test signal in the millimeter-wave frequency band. In Step P3, the primary channel transmits the test signal to the DUT. In Step P4, the measurement channel senses the RF signal radiated from the DUT. In Step P5, the first receiver 140 calculates an RF transmission characteristic of the DUT according to the reference gain, the reference output power, and a measured output power of the DUT. In one embodiment, the gain of the DUT (GoD) is calculated as the sum of the GoR and the measured output power of the DUT (POD), minus the POR. In other words, GoD=GoR+POD−POR, as shown in FIG. 4. The vector representation of this calculation is depicted in FIG. 4.

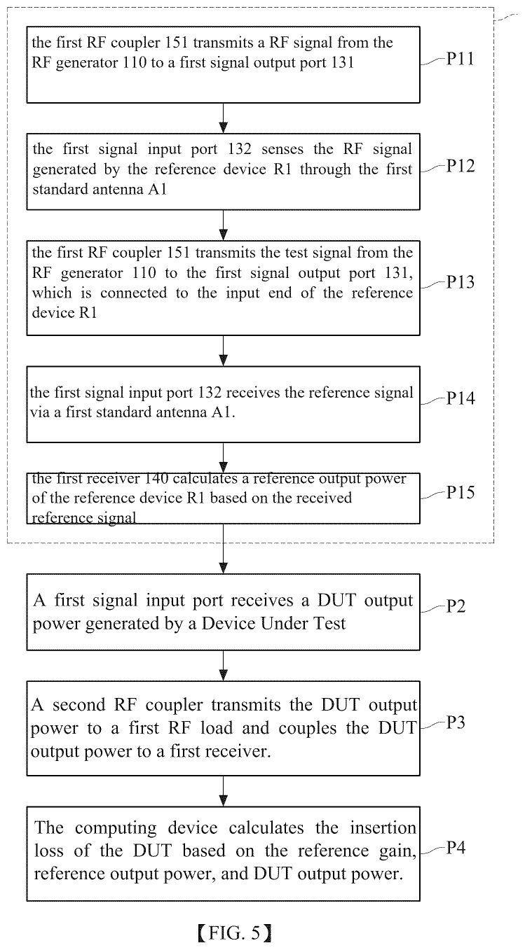

FIG. 5 illustrates a flowchart of a calibration method for an RF transmission characteristic, according to another embodiment of the present invention. The calibration method includes steps P11 through P14 and steps P2 through P5. In this embodiment, steps P11 through P14 correspond to an expanded version of step P1 in FIG. 3. Steps P11 through P14 are performed using the first VNA 100 and the reference device R1 as shown in FIG. 1, whereas steps P2 through P5 are performed using the first VNA 100 and the first DUT D1 as shown in FIG. 2. Refer to FIGS. 1 and 5, in step P11, the primary channel is electrically connected to a reference device R1, which may be configured to radiate a reference signal (also call as RF signal) within the far-field measurement range, for example, a standard antenna. Namely, the first RF coupler 151 transmits a RF signal from the RF generator 110 to a first signal output port 131. In step P12, the RF generator 110 provides the RF signal (also called as a test signal) in the mmWave frequency band. Then, the first signal input port 132 senses the RF signal generated by the reference device R1 through the first standard antenna A1. In step P13, the primary channel transmits the test signal to the reference device R1. Specifically, the first RF coupler 151 transmits the test signal from the RF generator 110 to the first signal output port 131, which is connected to the input end of the reference device R1. In step P14, the measurement channel senses a reference signal radiated from the reference device R1. Specifically, the first signal input port 132 receives the reference signal via a first standard antenna A1. In step P15, the first receiver 140 calculates a reference output power of the reference device R1 according to the received reference signal. Specifically, the second RF coupler 152 transmits the reference signal to the first RF load 120 while coupling the same signal to the first receiver 140. Steps P2 through P5 are the same as those described in the embodiment of FIG. 3. The difference between the embodiment in FIG. 5 and the embodiment in FIG. 3 lies in that the reference output power of the reference device R1 may be obtained by actual measurement (as in FIG. 5), or may be pre-stored values (as in FIG. 3).

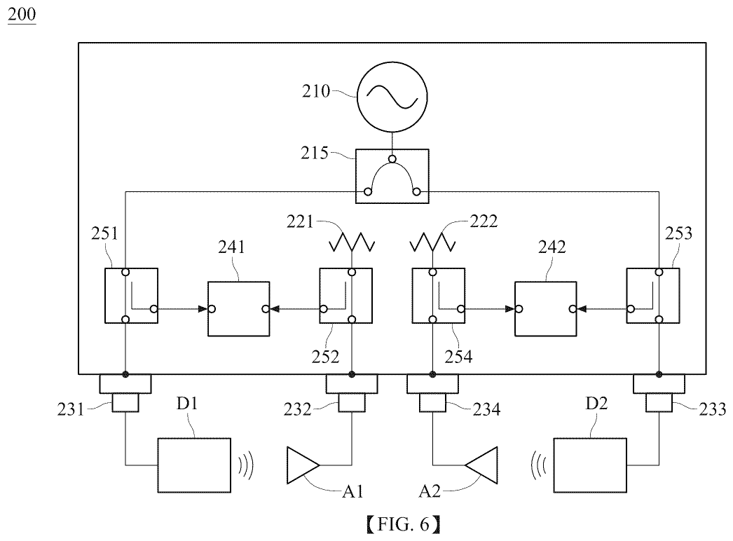

FIG. 6 illustrates a schematic diagram of an RF testing system according to an embodiment. As shown in FIG. 6, the RF testing system of this embodiment may be implemented as a second VNA 200. The second VNA 200 includes an RF generator 210, a power divider 215, a first RF load 221, a second RF load 222, a first signal output port 231, a first signal input port 232, a second signal output port 233, a second signal input port 234, a first receiver 241, a second receiver 242, a first RF coupler 251, a second RF coupler 252, a third RF coupler 253, and a fourth RF coupler 254. The power divider 215 is electrically connected to the RF generator 210 and the first RF coupler 251. The third RF coupler 253 is electrically connected to the power divider 215, the second signal output port 233, and the second receiver 242. The fourth RF coupler 254 is electrically connected to the second RF load 222, the second signal input port 234, and the second receiver 242. Additionally, the first RF coupler 251 is electrically connected to the power divider 215, the first signal output port 231, and the first receiver 241. The first signal output port 231 is electrically connected to a first DUT D1. The first signal input port 232 receives an RF signal wirelessly transmitted from the first DUT D1 via a first standard antenna A1. The second RF coupler 252 is electrically connected to the first RF load 221, the first signal input port 232, and the first receiver 241. Specifically, the second RF coupler 252 receives the RF signal from the first signal input port 232, transmits it to the first RF load 221, and simultaneously couples it to the first receiver 241 for measurement. Similarly, the third RF coupler 253 is electrically connected to the power divider 215, the second signal output port 233, and the second receiver 242. The second signal output port 233 is electrically connected to a second DUT D2. The second signal input port 234 receives an RF signal from the second DUT D2 via a second standard antenna A2. The fourth RF coupler 254 is electrically connected to the second RF load 222, the second signal input port 234, and the second receiver 242. Specifically, the fourth RF coupler 254 transmits the signal from the second signal input port 234 to the second RF load 222 while coupling it to the second receiver 242.

Compared to the first VNA 100 described previously, second VNA 200 utilizes the power divider 215 to distribute RF signals into two circuit sets. Each circuit set comprises two RF couplers 251, 252 (or 253, 254), signal output and input ports 231, 232 (or 223, 234), receivers 241 (or 242), and RF loads 221 (or 222). The selection and application of the power divider 215 in this embodiment are further described below.

The power divider 215 (also referred to as a power splitter) simultaneously distributes the RF test signal to facilitate multi-path measurements or analyses. The power divider 215 distributes the power of the input test signal either evenly or unevenly among multiple output ports 231, 233, enabling simultaneous transmission of the test signal through multiple signal paths 231, 233.

The operating principle of the power divider 215 is according to passive component design, typically employing resistive networks. Taking that the power divider 215 is a two-port power divider as an example, the two-port power divider internally contains three resistors, each having a resistance of approximately 16.67Ω, ensuring that all ports have an impedance of 50Ω. This arrangement achieves proper impedance matching, enabling the input signal power to be evenly distributed across two separate unidirectional transmission paths. As a result, each output port 231/233 receives half of the input power.

In a testing and measurement environment, the power divider 215 can be used to simultaneously distribute a single signal source to multiple RF test instruments, such as a spectrum analyzer and a power meter, allowing both spectrum and power measurements to be conducted concurrently. This configuration improves testing efficiency and ensures that each test instrument receives the same signal source, thereby enhancing the consistency and reliability of the measurement results.

According to this embodiment, the power divider 215 is used to divide an RF signal from the RF generator 210 into a first RF signal and a second RF signal. The power divider 215 may be used to distribute the amplitude and voltage of the RF signal. In one example, the power divider 215 is a mmWave power divider implemented using a Wilkinson splitter design. The first RF coupler 251 is electrically connected to the RF generator 210 via the power divider 215 and transmits the first RF signal to the first signal output port 231. The third RF coupler 253 is configured to transmit the second RF signal to the second signal output port 233, and to couple the second RF signal to the second receiver 242. The fourth RF coupler 254 is configured to transmit a second output signal from the second signal input port 234 to the second RF load 222, and to couple the second output signal to the second receiver 242.

As shown in FIG. 6, compared to the first VNA 100 in the previous embodiment, the second VNA 200 is capable of wirelessly measuring an RF transmission characteristic, such as the gain of the DUT (GoD), of both the first DUT D1 and the second DUT D2 simultaneously. The first signal output port 231 is communicatively connected to the first DUT D1. The wireless signal radiated from the first DUT D1 is received by the first signal input port 232 via a first standard antenna A1. Similarly, the second signal output port 233 is communicatively connected to the second DUT D2, and the wireless signal radiated from the second DUT D2 is received by the second signal input port 234 via a second standard antenna A2.

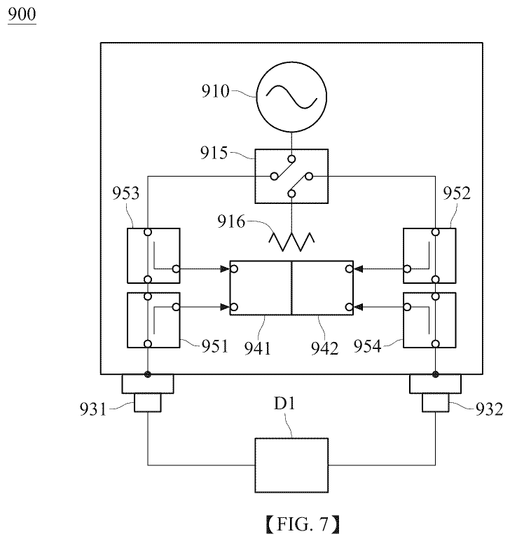

FIG. 7 illustrates a block diagram of a vector network analyzer (VNA) 900 representing prior art. As shown in FIG. 7, the VNA 900 includes an RF generator 910, a double pole double throw (DPDT) switch 915, a signal load 916, two ports 931 and 932, two receivers 941 and 942, and four signal couplers 951, 952, 953, and 954. The VNA 900 uses the DPDT switch 915 to selectively switch between multiple signal paths. At any given time, only one signal path is allowed to pass through, thus enabling sequential rather than simultaneous signal routing. In contrast, the second VNA 200 shown in the embodiment of FIG. 6 of the present invention uses a power divider 215 to evenly or unevenly distribute the power of a test signal and simultaneously transmit it to multiple unidirectional signal paths, such as the first signal output port 231 and the second signal input port 234.

Compared to the VNA 900 shown in FIG. 7, the second VNA 200 shown in FIG. 6 eliminates two signal couplers, namely coupler 951 and coupler 954. This structural simplification reduces signal energy loss, as illustrated in Table 1 below. Furthermore, relative to the VNA 900 in FIG. 7, the second VNA 200 of FIG. 6 improves the signal energy (dynamic range) at the second RF coupler 152 by up to approximately 2 decibels (dB).

Table 1 shows a comparison of signal energy loss across various signal couplers, where the gain under test is set to 28.00 GHz. The unit for the energy loss values is power in decibels-milliwatts (dBm):

| FIG. 7 | | FIG. 6 | |
|---|---|---|---|
| Signal Coupler | Energy Loss (dBm) | RF Coupler | Energy Loss (dBm) |
| 953 | −10.000 | 151 | −10.000 |
| 951 | −8.958 | none | 0.000 |
| 954 | −4.788 | none | 0.000 |
| 952 | −3.830 | 152 | −1.915 |

In summary, the RF testing equipment disclosed in the embodiments adopts a dual-channel interface design for unidirectional signal transmission, while the RF testing system adopts a four-channel interface design for unidirectional signal transmission. Based on the above-described architectures, the embodiments are not limited by the number of DUTs that may be measured simultaneously. Furthermore, the embodiments also disclose a calibration method for an RF transmission characteristic, according to the above RF testing equipment. Overall, the disclosed embodiments provides the advantages of reducing testing time and lowering the cost of test equipment, while improving the measurement efficiency of DUTs in over-the-air (OTA) test environments.

Although exemplary embodiments have been disclosed above, these embodiments are not intended to limit the scope of the disclosure. Any modifications or variations made within the spirit and scope of the appended claims are considered within the protection scope of the disclosure. The scope of protection is defined by the claims appended hereto.

What is claimed is:

1. A radio frequency (RF) testing equipment, comprising:
an RF signal generator, configured to provide a test signal in a millimeter-wave frequency band;
a primary channel, electrically connected to the RF signal generator, configured to connect to a device under test (DUT) and transmit the test signal to the DUT;
a measurement channel, configured to sense a RF signal radiated by the DUT; and
a receiver, electrically connected to the primary channel and the measurement channel, configured to calculate an RF transmission characteristic of the DUT according to the RF signal.

2. The RF testing equipment as recited in claim 1, wherein the primary channel comprises:
a first RF coupler, electrically connected to the RF signal generator and the receiver, configured to transmit the test signal; and
a first signal output port, electrically connected to the first RF coupler, configured to transmit the test signal to the DUT.

3. The RF testing equipment as recited in claim 2, wherein the measurement channel comprises:
a second RF coupler, electrically connected to the receiver;
a standard antenna, configured to sense and convert the RF signal within a far-field measurement range; and
a first signal input port, electrically connected to the standard antenna and the second RF coupler, configured to couple the RF signal to the second RF coupler.

4. An RF testing system, comprising:
an RF signal generator, configured to provide a test signal in a millimeter-wave frequency band;
two RF testing modules, each comprising the primary channel and the receiver as recited in claim 1, and the measurement channel as recited in claim 3; and
a power divider, electrically connected to the RF signal generator, the two RF testing modules, the power divider being configured to distribute the test signal to the two RF testing modules.

5. The RF testing system as recited in claim 4, wherein each of the two RF testing modules further comprises an RF load electrically connected to the second RF coupler, and the second RF coupler is configured to transmit the RF signal to the RF load and the receiver.

6. The RF testing system as recited in claim 4, wherein the power divider is a Wilkinson power divider.

7. A calibration method for an RF transmission characteristic, performed by the RF testing equipment as recited in claim 1, the method comprising:
acquiring, by the receiver, a reference gain from a reference device;
acquiring, by the receiver, a reference output power from a reference device;
providing, by the RF signal generator, the test signal in the millimeter-wave frequency band;
transmitting, by the primary channel, the test signal to the DUT;
sensing, by the measurement channel, the RF signal radiated from the DUT; and
calculating, by the receiver, the RF transmission characteristic of the DUT according to the reference gain, the reference output power, and a measured output power of the DUT.

8. The calibration method for the RF transmission characteristic as recited in claim 7, wherein the step of obtaining, by the receiver, the reference output power of the reference device comprises:
connecting, by the primary channel, the reference device;
transmitting, by the primary channel, the test signal to the reference device;
sensing, by the measurement channel, a reference signal radiated by the reference device; and
calculating, by the receiver, the reference output power of the reference device according to the reference signal.

9. The calibration method for the RF transmission characteristic as recited in claim 7, wherein the RF transmission characteristic is calculated as a sum of the reference gain and the measured output power of the DUT, minus the reference output power.
